(19) United States
(12) Patent Application Publication
(10) Pub. No.: US 2025/0344377 A1
(43) Pub. Date: Nov. 6, 2025

(54) SEMICONDUCTOR MEMORY DEVICE INCLUDING A VERTICAL CHANNEL TRANSISTOR AND METHOD OF MANUFACTURING THE SAME

(71) Applicant: SAMSUNG ELECTRONICS CO., LTD., SUWON-SI (KR)

(72) Inventors: Hyungki CHO, Suwon-si (KR); Minjeong CHOI, Suwon-si (KR)

(21) Appl. No.: 19/026,909

(22) Filed: Jan. 17, 2025

(30) Foreign Application Priority Data
May 3, 2024 (KR) 10-2024-0059429

(51) Int. Cl. H10B 12/00

(52) U.S. Cl. CPC H10B 12/488; H10B 12/053; H10B 12/315

(57) ABSTRACT

A semiconductor memory device includes: a bit line extending in a first direction on a substrate; a filling insulating layer including a channel trench disposed on the bit line and extending in a second direction crossing the first direction; a first gate insulating layer extending along a side surface and a lower surface of the filling insulating layer; a channel layer extending along a lower surface and a portion of a side surface of the first gate insulating layer; a word line disposed between the side surface of the filling insulating layer and the side surface of the first gate insulating layer; a gate isolation insulating layer disposed in the channel trench that is defined by the bit line and the channel layer; and a data storage pattern electrically connected to the channel layer, wherein at least one offset insulating layer is disposed on one side of the word line.

### CROSS-REFERENCE TO RELATED APPLICATION

This application claims priority under 35 U.S.C. § 119 to Korean Patent Application No. 10-2024-0059429, filed on May 3, 2024, in the Korean Intellectual Property Office, the disclosure of which is incorporated by reference herein in its entirety.

### TECHNICAL FIELD

Embodiments of the present inventive concept relate to a semiconductor memory device and a method of manufacturing the semiconductor memory device, and more particularly, to a semiconductor memory device including a vertical channel transistor (VCT) and a method of manufacturing the semiconductor memory device.

### DISCUSSION OF THE RELATED ART

As the integration density of semiconductor memory devices gradually increases, the integration density of semiconductor devices included in semiconductor memory devices also increases. Since the integration density of two-dimensional (2D) or planar semiconductor memory devices is primarily determined by an area occupied by a unit memory cell, the integration density may be affected by the level of technology of forming fine patterns. However, expensive equipment that may be needed to increase pattern fineness may set a limitation on increasing the integration density of the two-dimensional or planar semiconductor memory devices. Therefore, to increase the integration density of semiconductor devices, vertical channel transistors, instead of planar channel transistors that may be formed planarly on semiconductor substrates, have been under development.

### SUMMARY

According to embodiments of the present inventive concept, a semiconductor memory device includes: a bit line extending in a first direction on a substrate; a filling insulating layer including a channel trench that is disposed on the bit line and extending in a second direction crossing the first direction; a first gate insulating layer extending along a side surface and a lower surface of the filling insulating layer; a channel layer extending along a lower surface and a portion of a side surface of the first gate insulating layer; a word line disposed between the side surface of the filling insulating layer and the side surface of the first gate insulating layer; a gate isolation insulating layer disposed in the channel trench that is defined by the bit line and the channel layer; and a data storage pattern electrically connected to the channel layer, wherein at least one offset insulating layer is disposed on one side of the word line.

According to embodiments of the present inventive concept, a method of manufacturing a semiconductor memory device includes: forming a bit line extending in a first direction on a substrate; forming a gate isolation insulating layer in a channel trench that is disposed on the bit line and that extends in a second direction crossing the first direction; forming a channel layer extending along a side surface of the gate isolation insulating layer and a top surface of the bit line; forming a first gate insulating layer on the channel layer and the gate isolation insulating layer; and forming a first offset insulating layer on the first gate insulating layer.

### BRIEF DESCRIPTION OF THE DRAWINGS

The above and other aspects of the present inventive concept will become more apparent by describing in detail embodiments thereof, with reference to the accompanying drawings, in which:

FIG. 1 is a layout diagram of a semiconductor memory device according to embodiments of the present inventive concept;

FIG. 2 is a cross-sectional view of a semiconductor memory device according to embodiments of the present inventive concept, taken along line I-I′ of FIG. 1;

FIGS. 3A, 3B, 3C, 3D, 3E, and 3F are cross-sectional views illustrating examples of a first offset insulating layer of a semiconductor memory device according to an embodiment of the present inventive concept;

FIG. 4 is a cross-sectional view of a semiconductor memory device according to embodiments of the present inventive concept, taken along line I-I′ of FIG. 1.

FIGS. 5A, 5B, 5C, 5D, 5E and 5F are cross-sectional views illustrating examples of a second offset insulating layer of a semiconductor memory device according to an embodiment of the present inventive concept;

FIGS. 6, 7, 8, and 9 are cross-sectional views of a semiconductor memory device according to embodiments of the present inventive concept, taken along line I-I′ of FIG. 1;

FIG. 10 is a flowchart illustrating a method of manufacturing a semiconductor memory device according to embodiments of the present inventive concept;

FIGS. 11A, 11B, 11C, 11D, 11E, 11F, 11G, 11H, 11I, 11J, 11K, 11L, and 11M are cross-sectional views to describe a method of manufacturing the semiconductor memory device including a first offset insulating layer, according to embodiments of the present inventive concept; and

FIGS. 12A, 12B, 12C, 12D, 12E, 12F, 12G, 12H, 12I, 12J, and 12K are cross-sectional views to describe a method of manufacturing the semiconductor memory device including a second offset insulating layer, according to embodiments of the present inventive concept.

### DETAILED DESCRIPTION OF THE EMBODIMENTS

Hereinafter, embodiments of the present inventive concept will be described in detail with reference to the accompanying drawings. However, various alterations and modifications may be made to the embodiments. Here, the embodiments are not construed as limited to the disclosure and the drawings. The embodiments should be understood to include all changes, equivalents, and replacements within the idea and the technical scope of the disclosure.

The technical terms used herein is for the purpose of describing embodiments of the present inventive concept only and is not to be limiting of the embodiments of the present inventive concept. The singular forms “a”, “an”, and “the” are intended to include the plural forms as well, unless the context clearly indicates otherwise.

Unless otherwise defined, all terms, including technical and scientific terms, used herein have the same meaning as commonly understood by one of ordinary skill in the art to which embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

When describing the embodiments with reference to the accompanying drawings, like reference numerals may refer to like components and a repeated description related thereto may be omitted or briefly discussed.

In addition, terms such as first, second, A, B, (a), (b), and the like may be used to describe components of the embodiments. Each of these terms is not used to define an essence, order or sequence of a corresponding component but is used merely to distinguish the corresponding component from other component(s). It should be noted that if it is described in the specification that one component is “connected,” “coupled” or “joined” to another component, the former may be directly “connected,” “coupled,” and “joined” to the latter or “connected”, “coupled”, and “joined” to the latter via another component.

A component, which has the same common function as the component included in one embodiment, will be described by using the same name in other embodiments. Unless disclosed to the contrary, the description of any one embodiment of the present inventive concept may be applied to other embodiments of the present inventive concept, and the specific description of the repeated configuration will be omitted or briefly discussed.

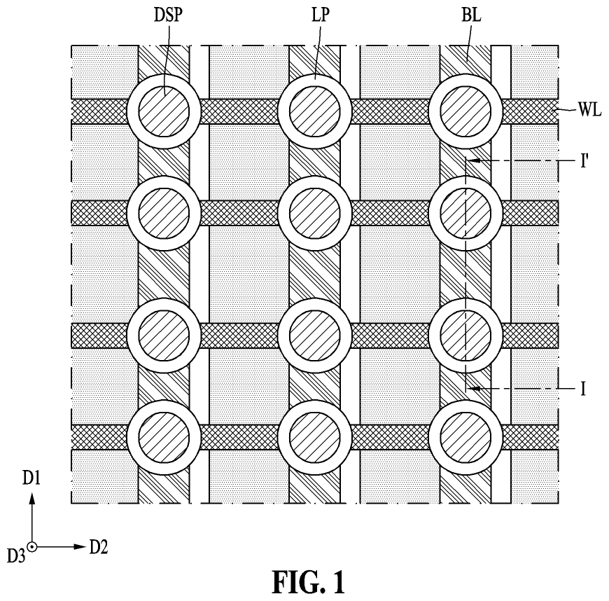

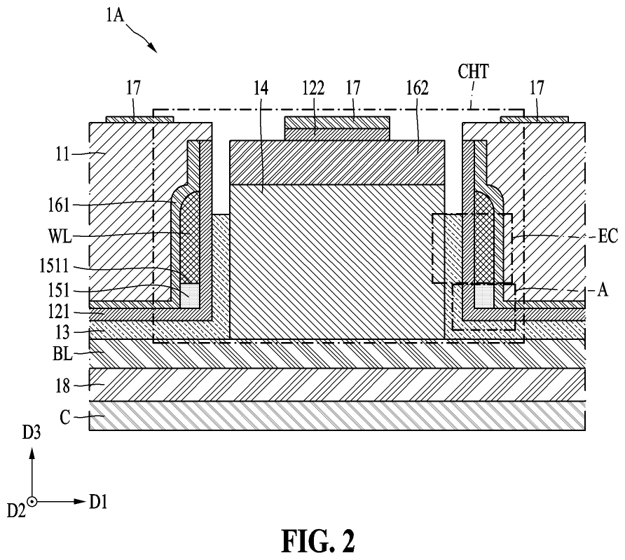

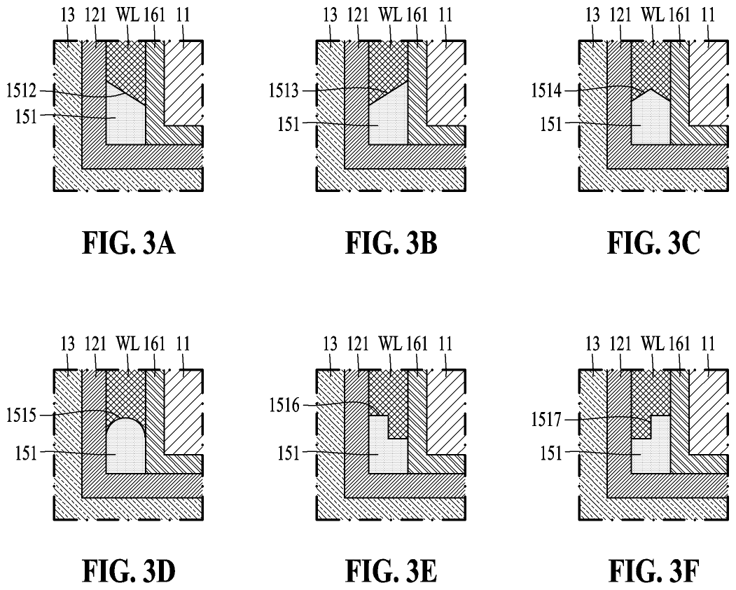

FIG. 1 is a layout diagram of a semiconductor memory device according to embodiments of the present inventive concept. FIG. 2 is a cross-sectional view of a semiconductor memory device according to embodiments of the present inventive concept, taken along line I-I′ of FIG. 1. FIGS. 3A to 3F are cross-sectional views illustrating examples of a first offset insulating layer of a semiconductor memory device according to an embodiment of the present inventive concept.

The semiconductor memory device according to embodiments of the present inventive concept may include memory cells, each including a vertical channel transistor (VCT).

Referring to FIGS. 1 and 2, a semiconductor memory device 1A may include a bit line BL, a filling insulating layer 11, which includes a channel trench CHT, a first gate insulating layer 121, a second gate insulating layer 122, a channel layer 13, a word line WL, a gate isolation insulating layer 14, at least one offset insulating layer 151 and 152, a first cover insulating layer 161, a second cover insulating layer 162, a support insulating layer 17, an insulating film 18, a gate poly layer 19, a landing pad LP, and a data storage pattern DSP.

A substrate C extending in a first direction D1 and a second direction D2 may be provided. The first direction D1 and the second direction D2 may cross each other and may be parallel to a top surface of the substrate C. The substrate C may be a semiconductor substrate. For example, the substrate C may be a silicon substrate. In addition, the substrate C may include other materials, such as silicon germanium, indium antimonide, lead telluride compound, indium arsenide, indium phosphide, gallium arsenide, or gallium antimonide, but the present inventive concept is not limited thereto.

The bit line BL may be disposed on the substrate C. The insulating film 18 may be disposed between the substrate C and the bit line BL. The insulating film 18 may have a peripheral gate structure. The peripheral gate structure may include a peripheral gate insulating film, a peripheral lower conductive pattern, and a peripheral upper conductive pattern.

The bit line BL may extend lengthwise in the first direction D1. For example, a plurality of bit lines BL may be provided and spaced apart from each other in the second direction D2.

The bit line BL may include, for example, at least one of doped polysilicon, a metal (e.g., Al, Cu, Ti, Ta, Ru, W, Mo, Pt, Ni, or Co), a conductive metal nitride (e.g., TiN, TaN, WN, NbN, TiAlN, TiSiN, TaSiN, or RuTiN), a conductive metal silicide, or a conductive metal oxide (e.g., PtO, RuO₂, IrO₂, SrRuO₃ (SRO), (Ba,Sr)RuO₃ (BSRO), CaRuO₃(CRO), or LSCo), but the present inventive concept is not limited thereto. The bit line BL may include a single layer or multiple layers including the above-described materials. The bit line BL may include a two-dimensional (2D) semiconductor material. For example, the 2D semiconductor material may include graphene, carbon nanotube, or a combination thereof.

The data storage pattern DSP may be electrically connected to a channel layer that will be described below. The landing pad LP may be disposed between the channel layer 13 and the data storage pattern DSP.

Landing pads LP may have various shapes, for example, a circular shape, an elliptical shape, a rectangular shape, a square shape, a rhombus shape, or a hexagonal shape. The landing pads LP may include conductive materials. The landing pads LP may include, for example, at least one of doped polysilicon, a conductive metal nitride, a conductive metal silicon nitride, a metal carbonitride, a conductive metal silicide, a conductive metal oxide, a 2D material, a metal, or a metal alloy.

Data storage patterns DSP may be disposed on the landing pads LP, respectively. The data storage patterns DSP may be arranged in a form of a matrix in the second direction D2 and the first direction D1. The data storage patterns DSP may completely or partially overlap the landing pads LP in a third direction D3. For example, each data storage pattern DSP may be in contact with an entirety of a top surface of a corresponding landing pad LP or a portion of the top surface of a corresponding landing pad LP.

The data storage patterns DSP may be capacitors. The data storage patterns DSP may include capacitor dielectric films interposed between storage electrodes and a plate electrode. Here, the storage electrodes may be in contact with the landing pads LP. In a plan view, the storage electrodes may have various shapes, for example, a circular shape, an elliptical shape, a rectangular shape, a square shape, a rhombus shape, or a hexagonal shape.

In addition, the data storage patterns DSP may be variable resistance patterns that may be switched between two resistance states by electrical pulses that are applied to a memory element. For example, the data storage patterns DSP may include phase-change materials having crystalline states changing depending on an amount of current, perovskite compounds, transition metal oxide, magnetic materials, ferromagnetic materials, or an antiferromagnetic material.

The filling insulating layer 11 may be a plurality of channel trenches CHT that is disposed on the bit line BL and that extends in the second direction D2 crossing the first direction D1. Neighboring channel trenches CHT may be spaced apart from each other in the first direction D1. Each of the channel trenches CHT may cross the bit line BL. A bottom surface of each of the channel trenches CHT may be provided by the bit line BL. A sidewall of each of the channel trenches CHT may be provided by the filling insulating layer 11. The filling insulating layer 11 may be a silicon nitride. The filling insulating layer 11 may be formed of a material with a relatively low dielectric constant.

The first gate insulating layer 121 may extend along a side surface and a bottom surface of the filling insulating layer 11. The first gate insulating layer 121 may be disposed between the word line WL and the channel layer 13. The first gate insulating layer 121 may extend in the second direction D2 parallel to the word line WL. The first gate insulating layer 121 may include, for example, a silicon oxide film, a silicon oxynitride film, a high-k dielectric insulating film having a dielectric constant that is greater than that of the silicon oxide film, or combinations thereof. In addition, the first gate insulating layer 121 may be formed of aluminum oxide (ALO).

The channel layer 13 may extend along a portion of a side surface and a bottom surface of the first gate insulating layer 121. The channel layer 13 may include one of, for example, an indium gallium zinc oxide (IGZO), an indium zinc oxide (IZO) doped with impurities, an indium oxide (InO), a zinc oxide (ZnO), a gallium oxide (GaO), a tin oxide (SnO), an aluminum zinc oxide (AZO), and/or an indium tin oxide (ITO). In the indium zinc oxide (IZO) doped with impurities, the impurities may include, for example, at least one of magnesium (Mg), strontium (Sr), barium (Ba), scandium (Sc), yttrium (Y), lanthanum (La), titanium (Ti), zirconium (Zr), hafnium (Hf), aluminum (Al), tin (Sn), or tantalum (Ta). Indium (In), gallium (Ga), and zinc (Zn) may be included in the same or different amounts from each other in the IGZO.

The word line WL may be disposed between the side surface of the filling insulating layer 11 and the side surface of the first gate insulating layer 121. The word line WL may extend lengthwise in the second direction D2. Neighboring word lines WL may be spaced apart from each other in the first direction D1. A top surface of the word line WL may be disposed at a level that is lower than a top surface of filling insulating layer 11. The word line WL may be formed along a sidewall of the channel trench CHT.

The word line WL may include, for example, at least one of doped polysilicon, a metal (e.g., Al, Cu, Ti, Ta, Ru, W, Mo, Pt, Ni, or Co), a conductive metal nitride (e.g., TiN, TaN, WN, NbN, TiAlN, TiSiN, TaSiN, or RuTiN), a conductive metal silicide, or a conductive metal oxide (e.g., PtO, RuO₂, IrO₂, SrRuO₃ (SRO), (Ba,Sr)RuO₃ (BSRO), CaRuO₃ (CRO), or LSCo), but the present inventive concept is not limited thereto. The word line WL may include a single layer or multiple layers including the above-described materials. The word line WL may include a 2D semiconductor material. For example, the 2D semiconductor material may include graphene, carbon nanotube, or a combination thereof.

The first cover insulating layer 161 may be disposed between the filling insulating layer 11 and the word line WL. The first cover insulating layer 161 may cover one surface of the word line WL that faces the filling insulating layer 11. In addition, the first cover insulating layer 161 may further cover one surface of the offset insulating layer 151 and 152 that will be described below, and a surface of the first gate insulating layer 121 that faces the filling insulating layer 11.

The first cover insulating layer 161 may include an insulating film that may be deposited by using a film forming technology having excellent step coverage, for example, a chemical vapor deposition (CVD), a physical vapor deposition (PVD), or an atomic layer deposition (ALD). For example, the first cover insulating layer 161 may include at least one of a silicon oxide, a silicon oxynitride, or a high-k dielectric material having a dielectric constant that is greater than that of the silicon oxide. For example, the high-k dielectric material may include a metal oxide or a metal oxynitride. For example, the high-k dielectric material may include at least one of SiN, HfO₂, HfSiO, HfSiON, HfTaO, HfTiO, HfZrO, ZrO₂, or Al₂O₃, but the present inventive concept is not limited thereto. In other words, the first cover insulating layer 161 may be formed of a material having a dielectric constant that is greater than that of the filling insulating layer 11, to effectively prevent an oxidation of the word line WL.

The gate isolation insulating layer 14 may fill a portion of the channel trench CHT that is defined by the bit line BL and side surfaces of the channel layer 13. The gate isolation insulating layer 14 may be, for example, a silicon nitride. The gate isolation insulating layer 14 may be formed of a material having a relatively low dielectric constant.

The second cover insulating layer 162 may be disposed on the gate isolation insulating layer 14. For example, the second cover insulating layer 162 may include at least one of a silicon oxide, a silicon oxynitride, or a high-k dielectric material having a dielectric constant that is greater than that of the silicon oxide. The high-k dielectric material may include a metal oxide or a metal oxynitride. For example, the high-k dielectric material may include at least one of SiN, HfO₂, HfSiO, HfSiON, HfTaO, HfTiO, HfZrO, ZrO₂, or Al₂O₃, but the present inventive concept is not limited thereto.

The second gate insulating layer 122 may be disposed on the second cover insulating layer 162. The second gate insulating layer 122 may cover at least a portion of a top surface of the second cover insulating layer 162, but embodiments of the present inventive concept are not necessarily limited thereto. The second gate insulating layer 122 may include, for example, a silicon oxide film, a silicon oxynitride film, a high-k dielectric material having a dielectric constant that is greater than that of the silicon oxide film, or a combination thereof. The second gate insulating layer 122 may be formed of, for example, aluminum oxide (ALO).

The support insulating layer 17 may be disposed on the filling insulating layer 11 and the second gate insulating layer 122. The support insulating layer 17 may cover at least a portion of the top surface of the filling insulating layer 11 and cover at least a portion of the top surface of the second gate insulating layer 122. However, embodiments of the present inventive concept are not necessarily limited thereto. For example, the support insulating layer 17 may include at least one of a silicon oxide, a silicon oxynitride, or a high-k dielectric material having a dielectric constant that is greater than that of the silicon oxide. The high-k dielectric material may include, for example, a metal oxide or a metal oxynitride. For example, the high-k dielectric material may include, for example, at least one of SiN, HfO₂, HfSiO, HfSiON, HfTaO, HfTiO, HfZrO, ZrO₂, or Al₂O₃, but the present inventive concept is not limited thereto.

At least one offset insulating layer 151 or 152 may be disposed on one side of the word line WL. Due to such a structure of the offset insulating layer 151 and 152, a distance between one side of the word line WL and the bit line BL or a distance between one side of the word line WL and a contact may be increased. The offset insulating layer 151 and 152 may extend in the second direction D2, similarly to the word line WL. The offset insulating layer 151, 152 may be formed of, for example, silicon dioxide (SiO₂) known as silica (SiO₂).

The first offset insulating layer 151 may be disposed between a lower side of the word line WL and the first gate insulating layer 121. A first boundary surface 1511 on which the word line WL and an upper end of the first offset insulating layer 151 are in contact with each other may be formed as a horizontal surface. For example, the first boundary surface 1511 may be an interface between the first offset insulating layer 151 and the word line WL. The first offset insulating layer 151 may function as an offset with respect to the word line WL.

Accordingly, a distance between the word line WL and the bit line BL may be increased. Based on the above structure, a strength of an electric field that is applied to a portion A that is between an effective channel EC and the bit line BL may be reduced. Here, the effective channel EC may be a section in which the channel layer 13, the first gate insulating layer 121, and the word line WL overlap each other in the first direction D1.

The first offset insulating layer 151 may be disposed under the word line WL, and accordingly, the strength of the electric field that is applied to the portion A that is between the effective channel EC and the bit line BL may be reduced. Thus, a movement of defects from the outside of the effective channel EC to the inside of the effective channel EC may be suppressed. In addition, a reliability may be increased by increasing a lifespan of an oxide semiconductor memory device.

The distance between the word line WL and the bit line BL may be adjusted by changing a length of the first offset insulating layer 151 in the third direction D3. Thus, the strength of the electric field that is applied to the portion A that is between the effective channel EC and the bit line BL may also be adjusted.

Referring to FIGS. 3A to 3F, the first offset insulating layer 151 may have various shapes. FIGS. 3A to 3F are enlarged diagrams illustrating a portion of the word line WL and a portion of the first offset insulating layer 151 of the semiconductor memory device 2.

Referring to FIG. 3A, a first boundary surface 1512 on which the word line WL and the upper end of the first offset insulating layer 151 are in contact with each other may be formed to be inclined in a downward direction (e.g., a diagonal downward direction) from the first gate insulating layer 121 to the first cover insulating layer 161. For example, the length (or, e.g., height) of the first offset insulating layer 151 may gradually decrease from the first gate insulating layer 121 to the first cover layer 161.

Referring to FIG. 3B, a first boundary surface 1513 on which the word line WL and the upper end of the first offset insulating layer 151 are in contact with each other may be formed to be inclined in an upward direction (e.g., a diagonal upward direction) from the first gate insulating layer 121 to the first cover insulating layer 161. For example, the length (or, e.g., height) of the first offset insulating layer 151 may gradually increase from the first gate insulating layer 121 to the first cover layer 161.

Referring to FIG. 3C, a first boundary surface 1514 on which the word line WL and the upper end of the first offset insulating layer 151 are in contact with each other may be formed such that a central portion of the first boundary surface 1514 may have a bent shape, such as a sharp wedge shape protruding toward the word line WL.

Referring to FIG. 3D, a first boundary surface 1515 on which the word line WL and the upper end of the first offset insulating layer 151 are in contact with each other may be formed such that a central portion of the first boundary surface 1515 may have a rounded shape protruding toward the word line WL.

Referring to FIG. 3E, a first boundary surface 1516 on which the word line WL and the upper end of the first offset insulating layer 151 are in contact with each other may be formed in a stepped shape descending from the first gate insulating layer 121 to the first cover insulating layer 161. For example, the first boundary surface 1516 may have a first level that is adjacent to the first gate insulating layer 121 and a second level that is lower than the first level and is between the first level and the first covering layer 161.

Referring to FIG. 3F, a first boundary surface 1517 on which the word line WL and the upper end of the first offset insulating layer 151 are in contact with each other may be formed in a stepped shape ascending from the first gate insulating layer 121 to the first cover insulating layer 161. For example, the first boundary surface 1517 may have a first level that is adjacent to the first gate insulating layer 121 and a second level that is higher than the first level and is between the first level and the first covering layer 161.

Based on various shapes of the first offset insulating layer 151 described above, a strength of an electric field that is applied to a portion that is between an effective channel and a bit line may be controlled in various directions.

Hereinafter, redundant descriptions that may be equally applicable among the technical concepts described above are omitted, and differences between other embodiments are mainly described.

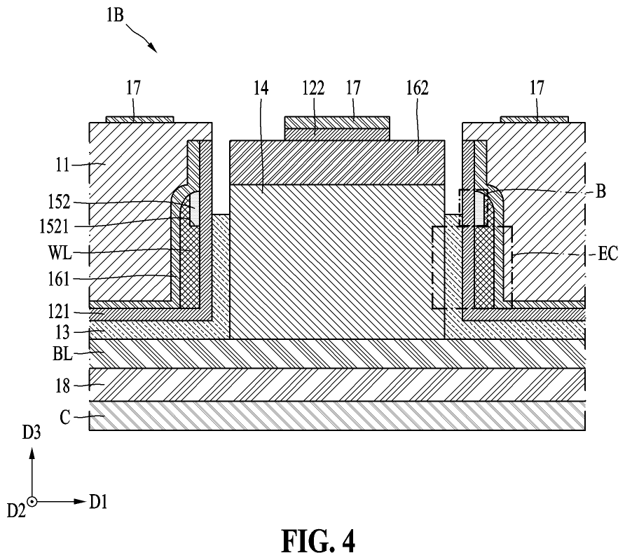

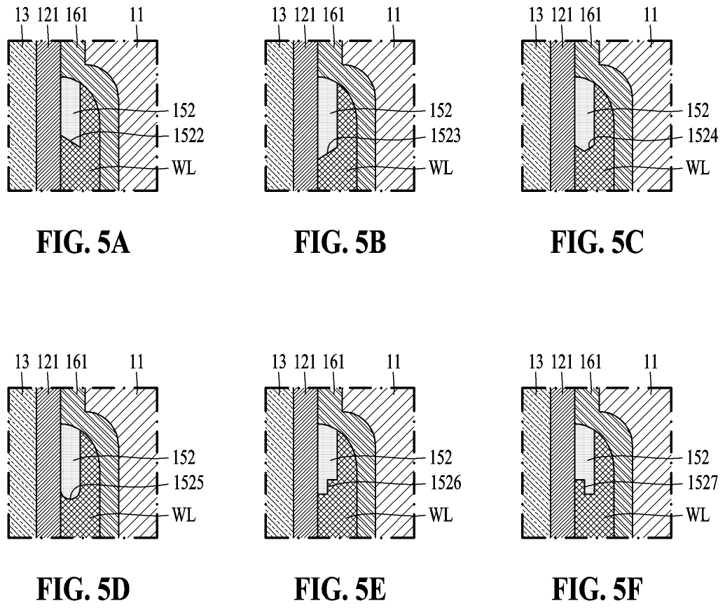

FIG. 4 is a cross-sectional view of a semiconductor memory device according to embodiments of the present inventive concept, taken along line I-I′ of FIG. 1. FIGS. 5A to 5F are cross-sectional views illustrating examples of a second offset insulating layer of a semiconductor memory device according to an embodiment of the present inventive concept.

Referring to FIG. 4, a second offset insulating layer 152 of a semiconductor memory device 1B may be disposed between an upper side of a word line WL and a first gate insulating layer 121. A second boundary surface 1521 on which the word line WL and a lower end of the second offset insulating layer 152 are in contact with each other may be formed as a horizontal surface. Thus, the second offset insulating layer 152 may function as an offset with respect to the word line WL.

Therefore, a distance between the word line WL and a contact may increase. Here, the contact may be defined by components that are disposed on a channel layer 13. Based on the above structure, a strength of an electric field that is applied to a portion B between an effective channel EC and the contact may be reduced.

By reducing the strength of the electric field that is applied to the portion B between the effective channel EC and the contact, it is possible to prevent defects from being moved from an outside of the effective channel EC to an inside of the effective channel EC. In addition, it is possible to increase a reliability by increasing a lifespan of an oxide semiconductor memory device.

Referring to FIGS. 5A to 5F, the second offset insulating layer 152 may have various shapes. FIGS. 5A to 5F are enlarged diagrams illustrating a portion of the word line WL and a portion of the second offset insulating layer 152 of the semiconductor memory device 4.

Referring to FIG. 5A, a second boundary surface 1522 on which the word line WL and the lower end of the second offset insulating layer 152 are in contact with each other may be formed to be inclined in a downward direction (e.g., a diagonal downward direction) from the first gate insulating layer 121 to a first cover insulating layer 161.

Referring to FIG. 5B, a second boundary surface 1523 on which the word line WL and the lower end of the second offset insulating layer 152 are in contact with each other may be formed to be inclined in an upward direction (e.g., a diagonal upward direction) from the first gate insulating layer 121 to the first cover insulating layer 161.

Referring to FIG. 5C, a second boundary surface 1524 on which the word line WL and the lower end of the second offset insulating layer 152 are in contact with each other may be formed such that a central portion of the second boundary surface 1524 may have a bent shape, such as a sharp wedge shape protruding toward the word line WL.

Referring to FIG. 5D, a second boundary surface 1525 on which the word line WL and the lower end of the second offset insulating layer 152 are in contact with each other may be formed such that a central portion of the second boundary surface 1525 may have a rounded shape protruding toward the word line WL.

Referring to FIG. 5E, a second boundary surface 1526 on which the word line WL and the lower end of the second offset insulating layer 152 are in contact with each other may be formed in a stepped shape ascending from the first gate insulating layer 121 to the first cover insulating layer 161. For example, the second boundary surface 1526 may have a first level that is adjacent to the first gate insulating layer 121 and a second level that is higher than the first level and is between the first level and the first covering layer 161.

Referring to FIG. 5F, a second boundary surface 1527 on which the word line WL and the lower end of the second offset insulating layer 152 are in contact with each other may be formed in a stepped shape descending from the first gate insulating layer 121 to the first cover insulating layer 161. For example, the second boundary surface 1527 may have a first level that is adjacent to the first gate insulating layer 121 and a second level that is lower than the first level and is between the first level and the first covering layer 161.

Based on various shapes of the second offset insulating layer 152 described above, a strength of an electric field that is applied to a portion that is between an effective channel and a contact may be controlled in various directions.

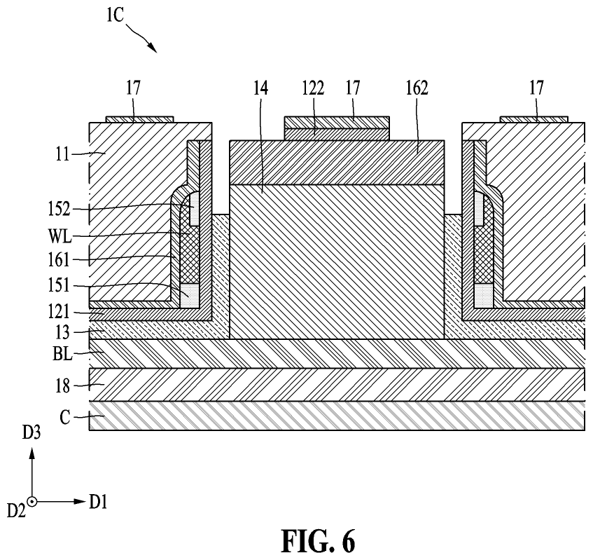

FIGS. 6 to 9 are cross-sectional views of a semiconductor memory device according to embodiments, taken along line I-I′ of FIG. 1.

Referring to FIG. 6, a semiconductor memory device 1C may include two offset insulating layers. A first offset insulating layer 151 may be disposed between a lower side of a word line WL and a first gate insulating layer 121, and a second offset insulating layer 152 may be disposed between an upper side of the word line WL and the first gate insulating layer 121.

A first boundary surface on which the word line WL and an upper end of the first offset insulating layer 151 are in contact with each other may be formed as a horizontal surface, an inclined surface, a stepped surface, or a surface of which a central portion protrudes toward the word line WL. In addition, a second boundary surface on which the word line WL and a lower end of the second offset insulating layer 152 are in contact with each other may be formed as a horizontal surface, an inclined surface, a stepped surface, or a surface of which a central portion protrudes toward the word line WL.

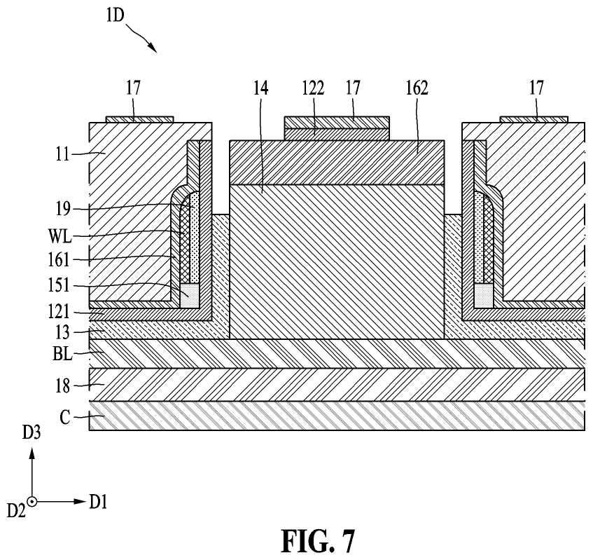

Referring to FIGS. 7 to 9, semiconductor memory devices 1D, 1E, and 1F may each include a gate poly layer 19 disposed between a first gate insulating layer 121 and a word line WL. The gate poly layer 19 may include at least one of doped polysilicon or doped polycrystalline silicon germanium (poly SiGe).

Referring to FIG. 7, a first offset insulating layer 151 of the semiconductor memory device 1D may be disposed between the first gate insulating layer 121 and a lower side of each of the word line WL and the gate poly layer 19. Thus, the first offset insulating layer 151 may function as an offset with respect to the word line WL.

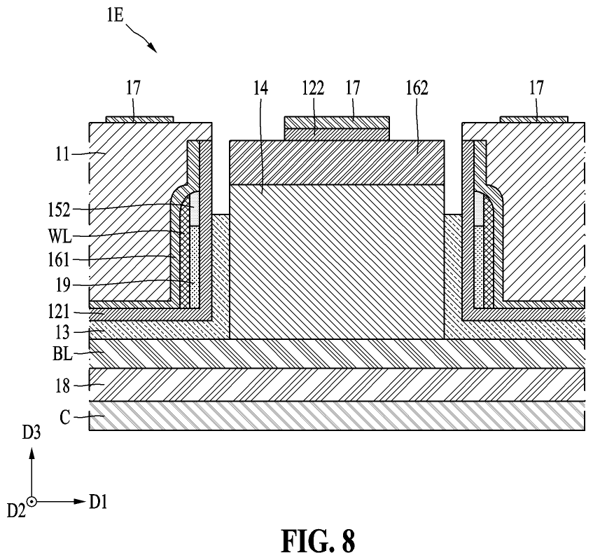

Referring to FIG. 8, a second offset insulating layer 152 of the semiconductor memory device 1E may be disposed on the gate poly layer 19. For example, the second offset insulating layer 152 may be formed in a space defined by a side surface of an upper portion of a word line WL, a top surface of the gate poly layer 19, and a side surface of the first gate insulating layer 121. Thus, the second offset insulating layer 152 may function as an offset with respect to the word line WL.

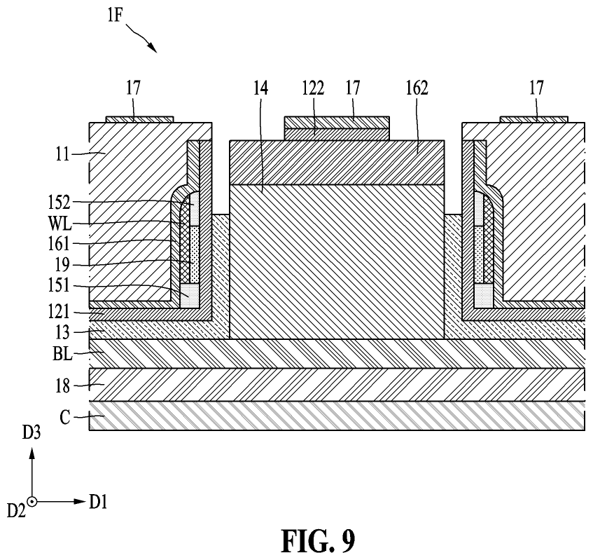

Referring to FIG. 9, the semiconductor memory device 1F may include two offset insulating layers. A first offset insulating layer 151 may be disposed between the first gate insulating layer 121 and a lower side of each of the word line WL and the gate poly layer 19. In addition, a second offset insulating layer 152 may be disposed on the gate poly layer 19 and between the word line WL and the first gate insulating layer 121. In other words, the second offset insulating layer 152 may be formed in a space defined by a side surface of an upper portion of a word line WL, a top surface of the gate poly layer 19, and a side surface of the first gate insulating layer 121.

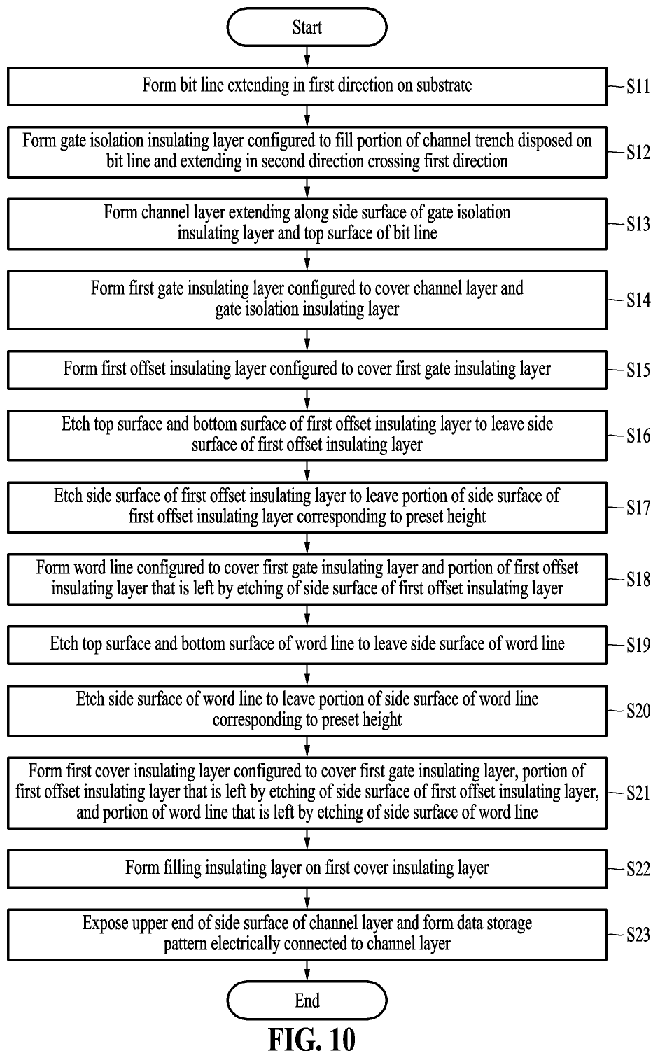

FIG. 10 is a flowchart illustrating a method of manufacturing a semiconductor memory device according to embodiments of the present inventive concept.

Referring to FIG. 10, the method may include the following: operation S11 of forming a bit line extending in a first direction on a substrate; operation S12 of forming a gate isolation insulating layer configured to fill a portion of a channel trench disposed on the bit line and extending in a second direction crossing the first direction; operation S13 of forming a channel layer extending along a side surface of the gate isolation insulating layer and a top surface of the bit line; operation S14 of forming a first gate insulating layer covering the channel layer and the gate isolation insulating layer; and operation S15 of forming a first offset insulating layer covering the first gate insulating layer.

The method may further include operation S16 of etching a top surface and a bottom surface of the first offset insulating layer to leave a side surface of the first offset insulating layer, and operation S17 of etching the side surface of the first offset insulating layer to leave a portion of the side surface of the first offset insulating layer corresponding to a preset height.

The method may further include operation S18 of forming a word line covering the first gate insulating layer and the portion of the first offset insulating layer that is left by the etching of the side surface of the first offset insulating layer, and operation S19 of etching a top surface and a bottom surface of the word line to leave a side surface of the word line.

The method may further include operation S20 of etching the side surface of the word line to leave a portion of the side surface of the word line corresponding to a preset height.

The method may further include the following: operation S21 of forming a first cover insulating layer covering the first gate insulating layer, the portion of the first offset insulating layer that is left by the etching of the side surface of the first offset insulating layer, and the portion of the word line that is left by the etching of the side surface of the word line; operation S22 of forming a filling insulating layer on the first cover insulating layer; and operation S23 of exposing an upper end of a side surface of the channel layer and forming a data storage pattern electrically connected to the channel layer.

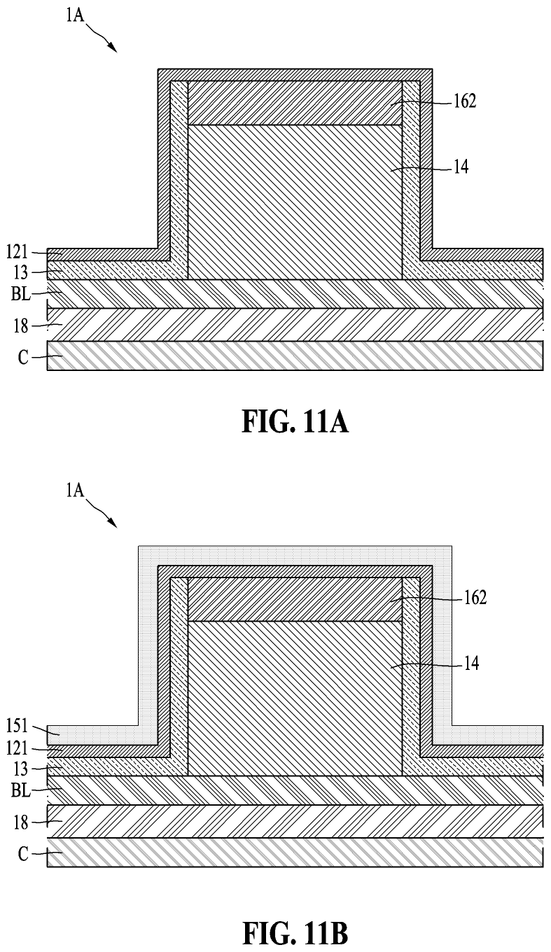

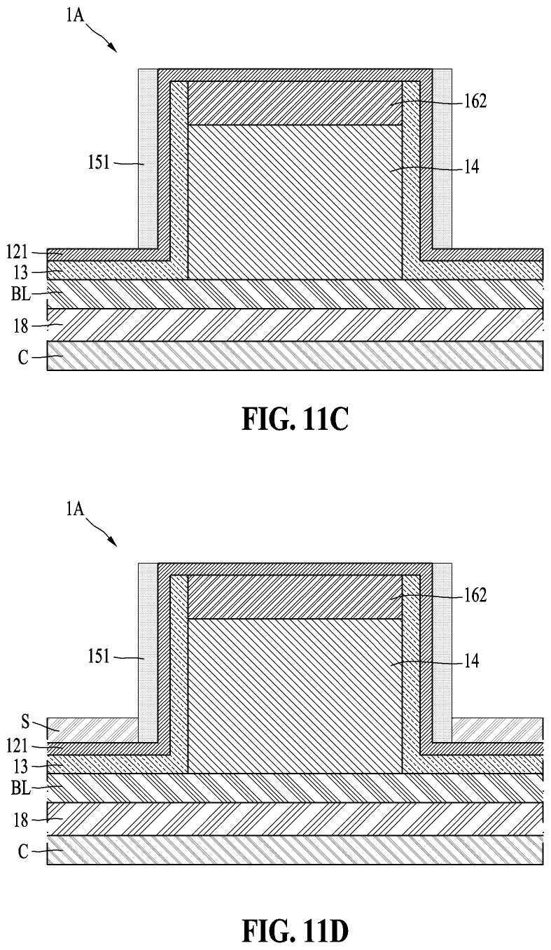

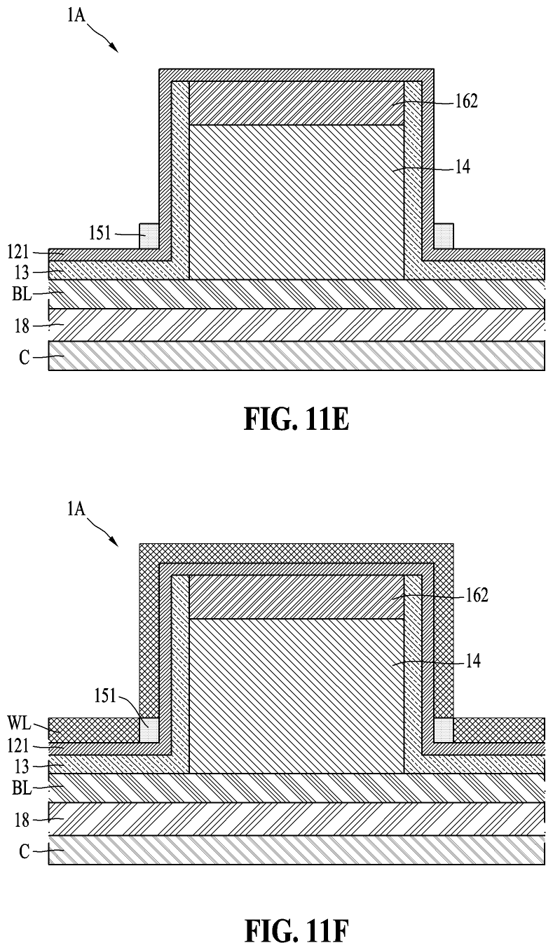

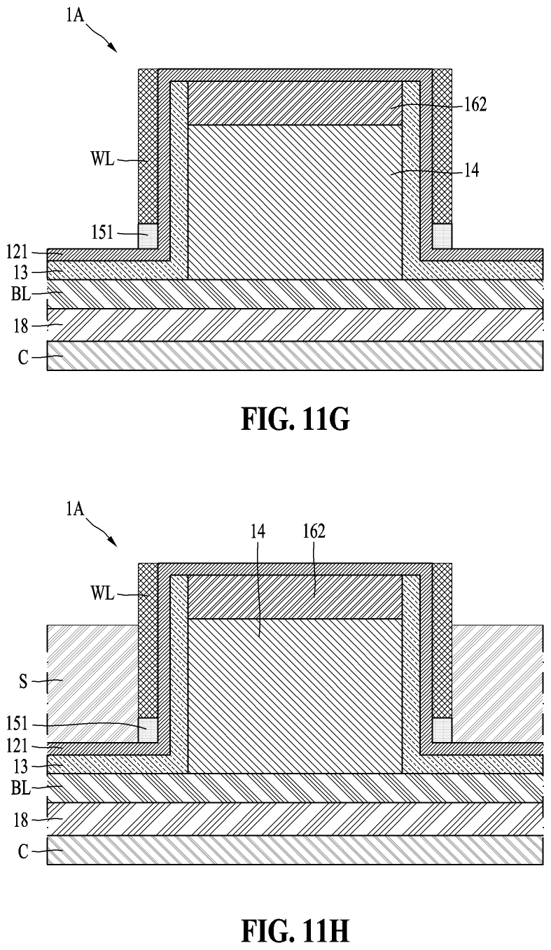

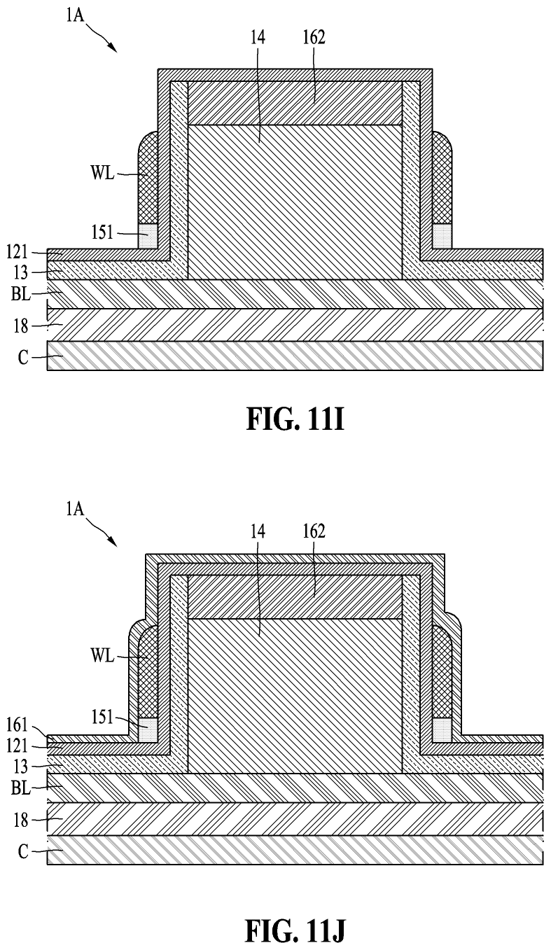

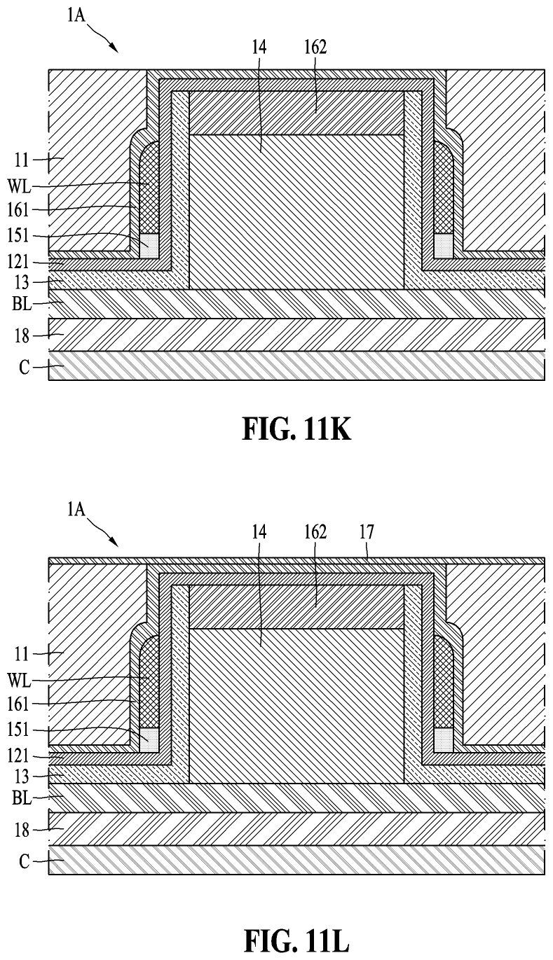

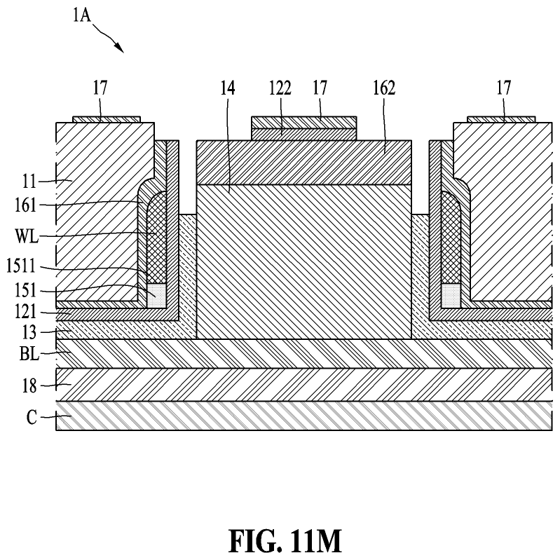

FIGS. 11A to 11M are cross-sectional views to describe a method of manufacturing the semiconductor memory device 1A of FIG. 1, according to an embodiment of the present inventive concept, including the first offset insulating layer 151.

Referring to FIG. 11A, the bit line BL extending in the first direction may be formed on the substrate C. The insulating film 18 may be formed between the substrate C and the bit line BL. The gate isolation insulating layer 14 may be formed to fill a portion of a channel trench that is disposed on the bit line BL and that extends in the second direction crossing the first direction. The second cover insulating layer 162 may be disposed on the gate isolation insulating layer 14. The channel layer 13, extending along the side surface of the gate isolation insulating layer 14, the side surface of the second cover insulating layer 162, and the top surface of the bit line BL, may be formed. The first gate insulating layer 121 may be formed to cover the channel layer 13 and the top surface of the second cover insulating layer 162.

Referring to FIG. 11B, the first offset insulating layer 151 may be formed to cover the first gate insulating layer 121. To form the first offset insulating layer 151, silicon dioxide (SiO₂) may be deposited.

Referring to FIG. 11C, an upper portion and a lower portion of the first offset insulating layer 151 may be removed by an etching process. Accordingly, only a lateral portion (e.g., a side surface) of the first offset insulating layer 151 that covers the side surface of the first gate insulating layer 121 may be left.

Referring to FIG. 11D, a sacrificial pattern S may be deposited on the first gate insulating layer 121 at a preset height. For example, the sacrificial pattern S may be deposited on an upper surface and/or a bottom surface of the first gate insulating layer 121. The sacrificial pattern S may be a spin-on hardmask (SOH). Thus, a portion of the side surface of the first offset insulating layer 151 corresponding to the preset height may be covered by the sacrificial pattern S, and the remaining portion of the side surface of the first offset insulating layer 151 may remain exposed.

Referring to FIG. 11E, the remaining portion of the side surface of the first offset insulating layer 151, which is exposed, may be removed by a side etching process. In addition, the sacrificial pattern S may be removed by an SOH ashing process. Accordingly, only a portion of the first offset insulating layer 151 with the preset height may be left.

Referring to FIG. 11F, the word line WL may be formed to cover the first gate insulating layer 121 and the first offset insulating layer 151.

Referring to FIG. 11G, an upper portion and a lower portion of the word line WL may be removed by an etching process. For example, the portion of the word line WL that extends in the third direction along the side wall of the first gate insulating layer 121 and is disposed on the upper surface of the first offset insulating layer 151 may remain, while the portions of the word line WL that extend on the channel layer 13 in the first direction and on the uppermost surface of the first gate insulating layer 121 may be removed by the etching process. Accordingly, only a lateral portion of the word line WL may be left.

Referring to FIG. 11H, another sacrificial pattern S may be deposited on the first gate insulating layer 121 at a preset height. For example, the sacrificial pattern S may be deposited on a lower surface of the first gate insulating layer 121. Thus, a portion of the side surface of the word line WL corresponding to the preset height may be covered by the sacrificial pattern S, and the remaining portion of the side surface of the word line WL may remain exposed.

Referring to FIG. 11I, the remaining portion of the side surfaces of the word line WL, which is exposed, may be removed by a side etching process. In addition, the sacrificial pattern S may be removed by an SOH ashing process. Accordingly, a portion of the word line WL with the preset height may be left. Thus, the first offset insulating layer 151 having the preset height may be formed on the side surface of the first gate insulating layer 121, and the word line WL having the preset height may be formed on the first offset insulating layer 151.

Referring to FIG. 11J, the first cover insulating layer 161 may be formed to cover the first gate insulating layer 121, the first offset insulating layer 151, and the word line WL.

Referring to FIG. 11K, the filling insulating layer 11 may be formed on the first cover insulating layer 161. For example, the filling insulating layer 11 may fill a space that is defined by the bottom surface and the side surface of the first cover insulating layer 161. Here, the top surface of the filling insulating layer 11 may be formed to have substantially the same height as the top surface of the first cover insulating layer 161.

Referring to FIG. 11L, the support insulating layer 17 may be formed to cover the top surface of the filling insulating layer 11 and the top surface of the first cover insulating layer 161.

Referring to FIG. 11M, an upper surface of the channel layer 13 may be exposed by an etching process. Subsequently, the channel layer 13 and the data storage pattern may be electrically connected to each other through a landing pad.

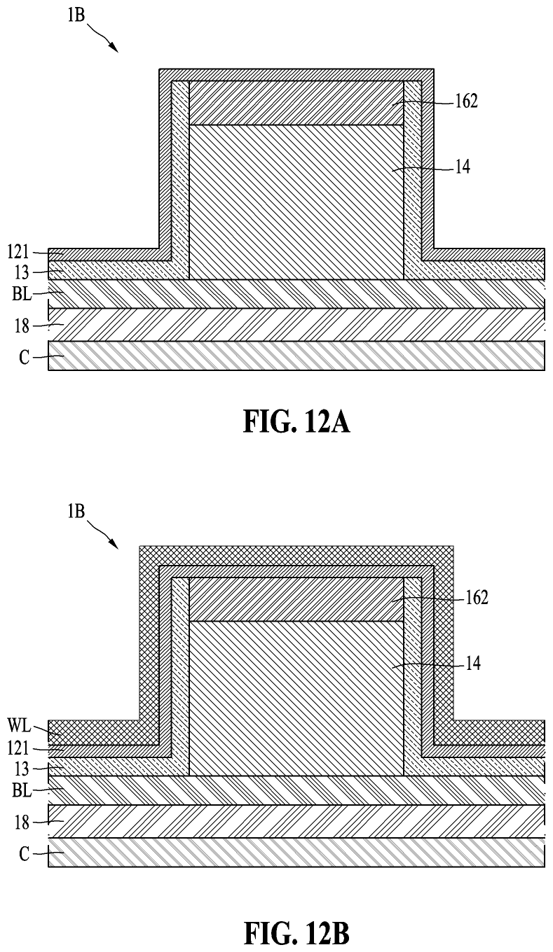

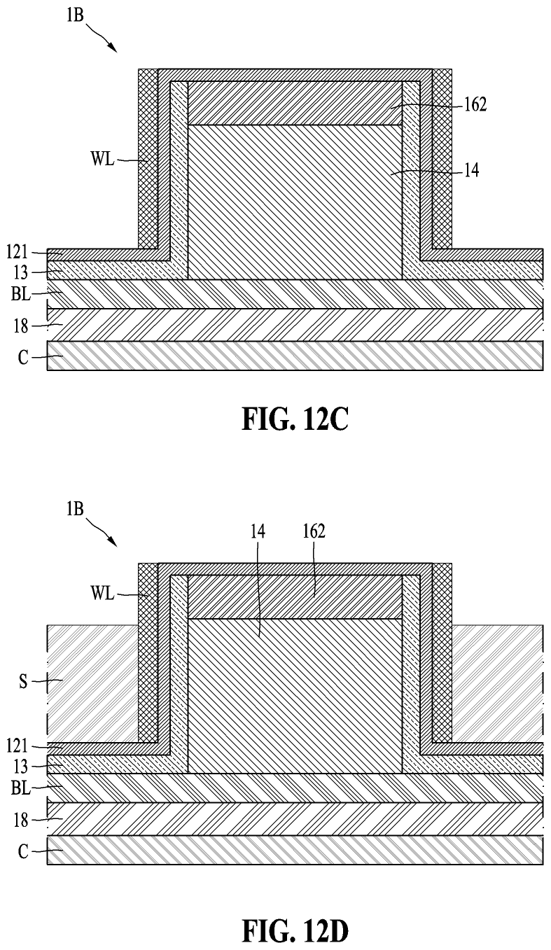

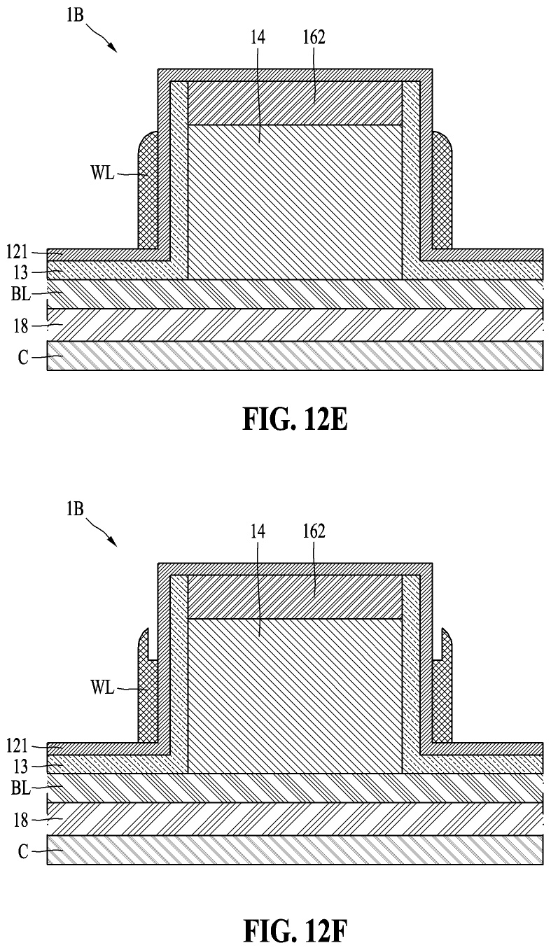

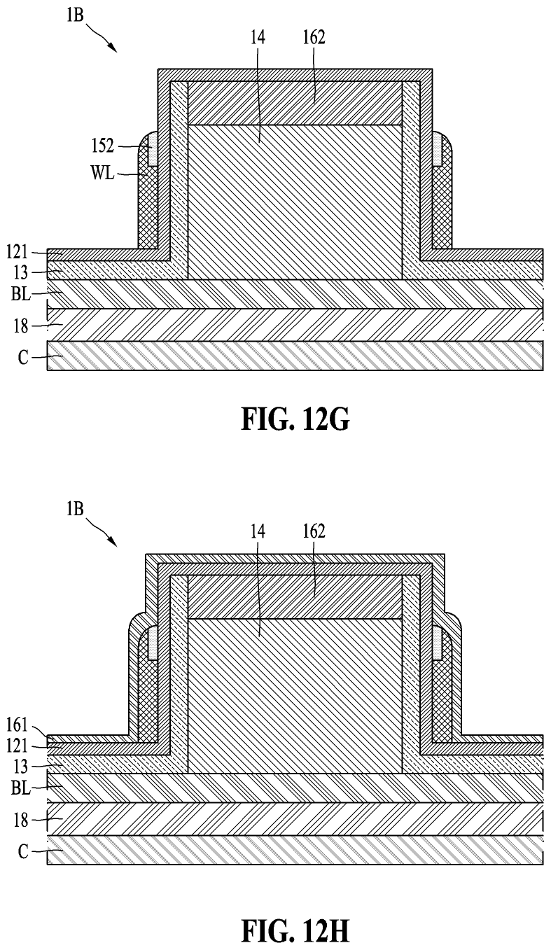

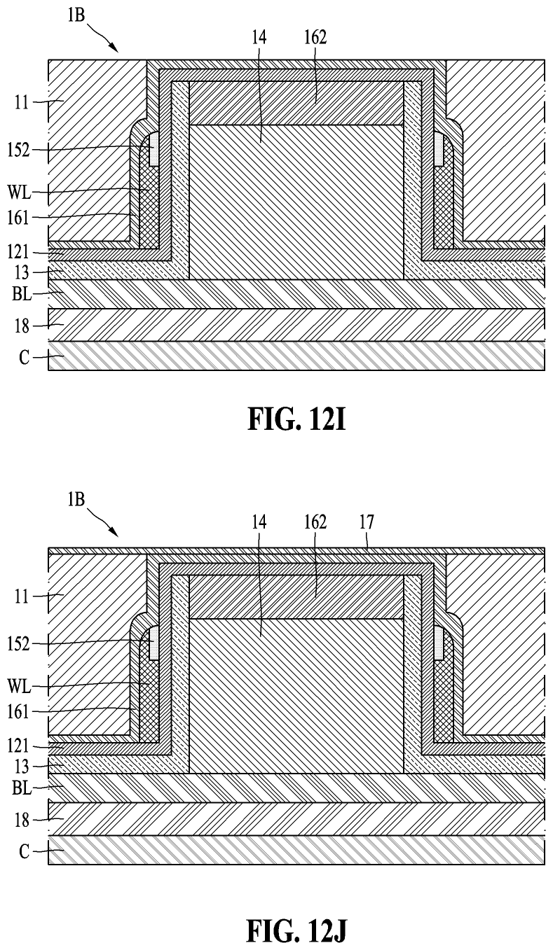

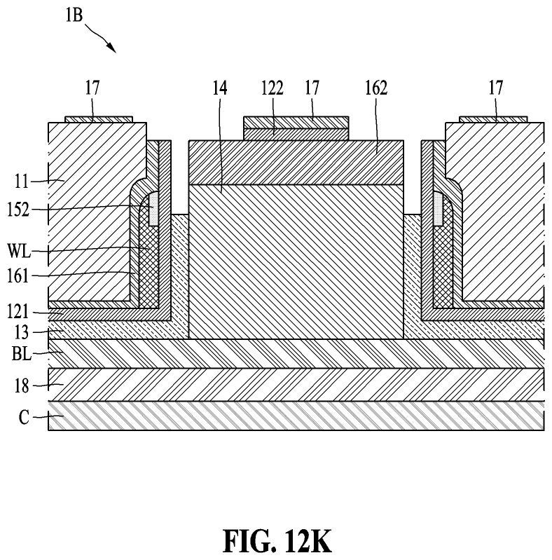

FIGS. 12A to 12K are cross-sectional views to describe a method of manufacturing the semiconductor memory device 1B of FIG. 4, according to an embodiment of the present inventive concept, including the second offset insulating layer 152.

Referring to FIG. 12A, a bit line BL extending in the first direction may be formed on a substrate C. An insulating film 18 may be formed between the substrate C and the bit line BL. A gate isolation insulating layer 14 may be formed to fill a portion of a channel trench that is disposed on the bit line BL and that extends in the second direction crossing the first direction. A second cover insulating layer 162 may be disposed on the gate isolation insulating layer 14. The channel layer 13, extending along a side surface of the gate isolation insulating layer 14, a side surface of the second cover insulating layer 162, and a top surface of the bit line BL, may be formed. The first gate insulating layer 121 may be formed to cover the channel layer 13 and a top surface of the second cover insulating layer 162.

Referring to FIG. 12B, the word line WL may be formed to cover the first gate insulating layer 121.

Referring to FIG. 12C, an upper portion and a lower portion of the word line WL may be removed by an etching process. Accordingly, only a lateral portion of the word line WL may be left

Referring to FIG. 12D, a sacrificial pattern S may be deposited on the first gate insulating layer 121 at a preset height. For example, the sacrificial pattern S may be deposited on a lower surface of the first gate insulating layer 121. The sacrificial pattern S may be an SOH. Thus, a portion of the side surface of the word line WL corresponding to the preset height may be covered by the sacrificial pattern S, and the remaining portion of the side surface of the word line WL may remain exposed.

Referring to FIG. 12E, the remaining portion of the side surface of the word line WL, which is exposed, may be removed by a side etching process. In addition, the sacrificial pattern S may be removed by an SOH ashing process. Accordingly, a portion of the word line WL with the preset height may be left. In other words, the word line WL having the preset height may be formed on a side surface of the first gate insulating layer 121.

Referring to FIG. 12F, an upper portion of the word line WL that faces the side surface of the first gate insulating layer 121 may be partially removed by an etching process to form a space between the word line WL and the side surface of the first gate insulating layer 121.

Referring to FIG. 12G, the second offset insulating layer 152 may be formed in a portion of the word line WL that is left after the etching process. For example, the second offset insulating layer 152 may be formed in the space that was formed between the word line WL and the side surface of the first gate insulating layer 121. Accordingly, the second offset insulating layer 152 may be disposed between the upper side of the word line WL and the first gate insulating layer 121.

Referring to FIG. 12H, the first cover insulating layer 161 may be formed to cover the first gate insulating layer 121, the second offset insulating layer 152, and the word line WL.

Referring to FIG. 12I, a filling insulating layer 11 may be formed on the first cover insulating layer 161. For example, the filling insulating layer 11 may fill a space that is defined by a bottom surface and a side surface of the first cover insulating layer 161. Here, a top surface of the filling insulating layer 11 may be formed to have substantially the same height as a top surface of the first cover insulating layer 161.

Referring to FIG. 12J, a support insulating layer 17 may be formed to cover the top surface of the filling insulating layer 11 and the top surface of the first cover insulating layer 161.

Referring to FIG. 12K, an upper surface of the channel layer 13 may be exposed by an Subsequently, the channel layer 13 and a data storage pattern may be etching process. electrically connected to each other through a landing pad.

As described above, in the semiconductor memory device and the method of manufacturing the semiconductor memory device, an offset insulating layer may be disposed on or under a word line, to reduce a strength of an electric field that is between an effective channel and a bit line or between the effective channel and a contact. In addition, a distance between a word line and a bit line or a distance between the word line and a contact may be increased, by using the offset insulating layer. Thus, it is possible to suppress a movement of defects from an outside of the effective channel to an inside of the effective channel, and to increase the reliability of the semiconductor memory device.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor memory device comprising:
a bit line extending in a first direction on a substrate;
a filling insulating layer comprising a channel trench that is disposed on the bit line and extending in a second direction crossing the first direction;
a first gate insulating layer extending along a side surface and a lower surface of the filling insulating layer;
a channel layer extending along a lower surface and a portion of a side surface of the first gate insulating layer;
a word line disposed between the side surface of the filling insulating layer and the side surface of the first gate insulating layer;
a gate isolation insulating layer disposed in the channel trench that is defined by the bit line and the channel layer; and
a data storage pattern electrically connected to the channel layer,
wherein at least one offset insulating layer is disposed on one side of the word line.

2. The semiconductor memory device of claim 1, wherein a first offset insulating layer is disposed between a lower side of the word line and the first gate insulating layer.

3. The semiconductor memory device of claim 2, wherein a first boundary surface, on which the word line and an upper end of the first offset insulating layer are in contact with each other, is formed as a horizontal surface, an inclined surface, a stepped surface, or a surface of which a central portion protrudes toward the word line.

4. The semiconductor memory device of claim 1, wherein a second offset insulating layer is disposed between an upper side of the word line and the first gate insulating layer.

5. The semiconductor memory device of claim 4, wherein a second boundary surface, on which the word line and a lower end of the second offset insulating layer are in contact with each other, is formed as a horizontal surface, an inclined surface, a stepped surface, or a surface of which a central portion protrudes toward the word line.

6. The semiconductor memory device of claim 1, wherein
the at least one offset insulating layer comprises a first offset insulating layer and a second offset insulating layer,
the first offset insulating layer is disposed between a lower side of the word line and the first gate insulating layer, and
the second offset insulating layer is disposed between an upper side of the word line and the first gate insulating layer.

7. The semiconductor memory device of claim 6, wherein
a first boundary surface, on which the word line and an upper end of the first offset insulating layer are in contact with each other, is formed as a horizontal surface, an inclined surface, a stepped surface, or a surface of which a central portion protrudes toward the word line, and
a second boundary surface, on which the word line and a lower end of the second offset insulating layer are in contact with each other, is formed as a horizontal surface, an inclined surface, a stepped surface, or a surface of which a central portion protrudes toward the word line.

8. The semiconductor memory device of claim 1, further comprising:
a first cover insulating layer disposed between the filling insulating layer and the word line,
wherein the first cover insulating layer covers one surface of the word line that faces the filling insulating layer.

9. The semiconductor memory device of claim 8, wherein the first cover insulating layer further covers one surface of the offset insulating layer, which faces facing the filling insulating layer, and one surface of the first gate insulating layer, which faces the filling insulating layer.

10. The semiconductor memory device of claim 1, further comprising:
a gate poly layer disposed between the first gate insulating layer and the word line.

11. The semiconductor memory device of claim 1, further comprising:
a second cover insulating layer disposed on the gate isolation insulating layer.

12. The semiconductor memory device of claim 11, further comprising:
a second gate insulating layer disposed on the second cover insulating layer.

13. The semiconductor memory device of claim 12, further comprising:
a support insulating layer disposed on the filling insulating layer and the second gate insulating layer.

14. The semiconductor memory device of claim 1, further comprising:
an insulating film disposed between the bit line and the substrate.

15. The semiconductor memory device of claim 1, further comprising:
a landing pad disposed between the channel layer and the data storage pattern.

16. A method of manufacturing a semiconductor memory device, the method comprising:
forming a bit line extending in a first direction on a substrate;
forming a gate isolation insulating layer in a channel trench that is disposed on the bit line and that extends in a second direction crossing the first direction;
forming a channel layer extending along a side surface of the gate isolation insulating layer and a top surface of the bit line;
forming a first gate insulating layer on the channel layer and the gate isolation insulating layer; and
forming a first offset insulating layer on the first gate insulating layer.

17. The method of claim 16, further comprising:
etching an upper portion and a lower portion of the first offset insulating layer to leave a lateral portion of the first offset insulating layer; and
etching the lateral portion of the first offset insulating layer to leave a portion of the lateral portion of the first offset insulating layer corresponding to a preset height.

18. The method of claim 17, further comprising:
forming a word line that covers the first gate insulating layer and the portion of the first offset insulating layer that is left by the etching of the lateral portion of the first offset insulating layer; and
etching an upper portion and a lower portion of the word line to leave a lateral portion of the word line.

19. The method of claim 18, further comprising:
etching the lateral portion of the word line to leave a portion of the lateral portion of the word line corresponding to a preset height.

20. The method of claim 19, further comprising:
forming a first cover insulating layer on the first gate insulating layer, the portion of the first offset insulating layer that is left by the etching of the lateral portion of the first offset insulating layer, and the portion of the word line that is left by the etching of the lateral portion of the word line;
forming a filling insulating layer on the first cover insulating layer;
exposing an upper surface of the channel layer; and
forming a data storage pattern that is electrically connected to the channel layer.
